(19) United States
(12) Patent Application Publication
(10) Pub. No.: US 2014/0187137 A1
(43) Pub. Date: Jul. 3, 2014

(54) AIR-FLOWING APPARATUS

(71) Applicant: LAW-CHAIN COMPUTER TECHNOLOGY CO., LTD., (US)

(72) Inventors: KUAN-HSIUNG YANG, Kaohsiung City (TW); FANG-HSIEN WU, Kaohsiung City (TW); YU-KUN LIN, Kaohsiung City (TW)

(73) Assignee: LAW-CHAIN COMPUTER TECHNOLOGY CO., LTD., Kaohsiung City (TW)

(21) Appl. No.: 13/728,643

(22) Filed: Dec. 27, 2012

(51) Int. Cl. H05K 5/02

(52) U.S. Cl. CPC H05K 5/02
USPC 454/184

(57) ABSTRACT

Disclosed is an air-flowing apparatus comprising: a cabinet group having at least one cabinet, and each cabinet having a plurality of temperature controlling zones; a temperature sensing device provided in proximity to each cabinet, and each of the plurality of temperature controlling zones provided with at least one temperature sensing member; a plurality of speed-variable heat dissipation devices, each temperature controlling zone provided with at least one speed-variable heat dissipation device; and a temperature controlling device having a temperature signal receiving component and a zone control outputting component, the temperature signal receiving component coupled to the temperature sensing device, and the zone control outputting component coupled to the speed-variable heat dissipation device. And thus it achieves an effect of accurate temperature control of the cabinet.

### FIELD OF THE INVENTION

The present invention relates to an air-flowing apparatus which accurately flows the air to desire locations of a machine room that stores machines, such as computers, and more particularly to an air-flowing apparatus which senses temperature of the machine room by a plural temperature sensing members and timely controls speed of a speed-variable heat dissipation devices, a refrigerating device and an air flowing device to perform a micro-control of temperature and maintain air of heat exchange. Thus the air-flowing apparatus achieves an effect of power saving, keeps normal operation of machines, and reduces a probability of shutdown or failure of machines.

### BACKGROUND OF THE INVENTION

Large business places, such as large computer companies, department stores, and telecommunications companies, always require to have a machine room for placing operating machines. Since a large number of operating machines and computer servers are placed in the machine room, there usually generates a huge amount of heat produced by the operating machines and computer servers. And thus, when operating machines and computer servers are not, able to operate under a high temperature, it is unavoidable to be shutdown or be failed for operation. This leads heavy losses. Thus, in the conventional manner, it usually provides an air-conditioning system to lower temperature of a machine room to maintain normal operation of the operating machines and computer servers.

The conventional air-conditioning system provides temperature sensors to sense temperature. However, the wiring installation for the conventional temperature sensors is complicated. Therefore, the conventional temperature sensors is merely applied in only a partition of the whole machine room. Accordingly, only a part of space of the whole machine room are sensed by the sensors. Moreover, a heat dissipation devices such as fans are not functioned as one able to be controlled to have variable rotating speed for sake of power saving. In detail, the temperature sensed by conventional temperature sensor is merely the temperature of the partial area of the whole machine room. It, therefore, causes the reason of energy waste since when there are only some machines with abnormal temperature, including temperature too high or too low, the conventional air-conditioning system will need to adjust the temperature of the whole machine room.

For this reason, although the conventional air-conditioning system is able to adjust temperature, an effectiveness of temperature management is poor. It cannot perform temperature control for each operating machine or computer server by using the conventional temperature sensor. Further, the conventional air-conditioning system is not provided with a temperature sensing device having higher efficacy. Moreover, the conventional air-conditioning system is not able to separately control the individual area of the whole machine room.

### SUMMARY OF THE INVENTION

Accordingly, the present invention overcomes the drawbacks of the prior art, and provides a temperature sensing device to sense temperature of a cabinet, and thus each temperature controlling zone of each cabinet is accurately adjusted for maintaining normal operation of machines in the cabinet with a suitable temperature. Further, it provides a cold channel and a hot channel formed between each cabinet group. The operation of heat exchange is performed by allowing cold air from the cold channel to maintain or cool down the temperature of operating machine and by allowing hot air to move out thorough the hot channel.

The present invention overcomes the drawbacks of the prior art, and provides an air-flowing apparatus. The air-flowing apparatus includes a cabinet group, a temperature sensing device, a plurality of speed-variable heat dissipation devices, and a temperature controlling device. The cabinet group has at least one cabinet, and each cabinet has a plurality of temperature controlling zones. The temperature sensing device is provided in proximity to each cabinet, and each of the plurality of temperature controlling zones is provided with at least one temperature sensing member. Each temperature controlling zone is provided with at least one speed-variable heat dissipation device. The temperature controlling device has a temperature signal receiving component and a zone control outputting component, the temperature signal receiving component is coupled to the temperature sensing device, and the zone control outputting component is coupled to the speed-variable heat dissipation device.

In a preferred embodiment of the present invention, the temperature controlling device is remotely connected a central control room.

In a preferred embodiment of the present invention, the temperature sensing device is a temperature optical fiber cable.

In a preferred embodiment of the present invention, the temperature sensing device is a plurality of temperature sensors.

In a preferred embodiment of the present invention, a top of the cabinet group is provided with a top blocking part.

In a preferred embodiment of the present invention, it further includes a carrier board and an air flowing device, the carrier board has an air channel which is formed therein, the air flowing device is communicated with the air channel, the cabinet group includes a plurality of cabinets and has a refrigerating device and a cold channel which is formed between the plurality of cabinets, the cold channel has an air opening, and the refrigerating device is provided with a transporting part.

In a preferred embodiment of the present invention, a side of the cabinet group is configured with the refrigerating device.

In a preferred embodiment of the present invention, the temperature controlling device controls and is coupled to the speed-variable heat dissipation device, the refrigerating device and the air flowing device.

In a preferred embodiment of the present invention, a plurality of cabinet groups are provided, and each cabinet group has a corresponding temperature controlling device.

In a preferred embodiment of the present invention, there is provided with a hot channel between a back of the cabinet group and a back of another cabinet group.

In a preferred embodiment of the present invention, the temperature optical fiber cable is sinuously provided around the plurality of temperature controlling zones.

In a preferred embodiment of the present invention, the temperature controlling device separately controls the plurality of speed-variable heat dissipation devices.

In a preferred embodiment of the present invention, a back of the refrigerating device is provided with a speed-variable heat dissipation device whose rate of heat dissipation is changed and controlled by the temperature controlling device according to a sense of the temperature sensing device.

By the above means, the present invention is able to accurately monitor temperature by accurately sensing temperature of each temperature controlling zone of each cabinet through a lot of temperature sensing members of the temperature sensing device, and control speed of a speed-variable heat dissipation device, a refrigerating device and air flowing device respectively to perform micro control of temperature and heat exchange of gas. Thus the air-flowing apparatus has an effect of power saving and maintaining normal operation of a machine, and reduces a probability of shutdown or failure.

### BRIEF DESCRIPTION OF THE DRAWINGS

The structure and the technical means adopted by the present invention to achieve the above and other objects can be best understood by referring to the following detailed description of the preferred embodiments and the accompanying drawings.

FIG. 1 is a stereogram illustrating the first embodiment according to the present invention;

FIG. 2 is another the stereogram illustrating the first embodiment according to the present invention;

FIG. 3 is a stereogram illustrating the second embodiment according to the present invention;

FIG. 4 is a schematic diagram illustrating cold channel and hot channel of the second embodiment according to the present invention;

FIG. 5 is a stereogram illustrating the third embodiment according to the present invention;

FIG. 6A is a schematic diagram illustrating that the temperature optical fiber cable of the second embodiment according to the present invention is build the front of the cabinet;

FIG. 6B is a schematic diagram illustrating that the temperature optical fiber cable of the second embodiment according to the present invention is build the back of the cabinet;

FIG. 7A is another schematic diagram illustrating that the temperature optical fiber cable of the second embodiment according to the present invention is build the front of the cabinet;

FIG. 7B is another schematic diagram illustrating that the temperature optical fiber cable of the second embodiment according to the present invention is build the back of the cabinet;

FIG. 8 is a schematic diagram illustrating the flow of cold air and hot air of the second embodiment according to the present invention; and

FIG. 9 is a schematic diagram illustrating the remote monitor of the second embodiment according to the present invention.

### DETAILED DESCRIPTION OF THE PREFERRED EMBODIMENTS

### The First Embodiment

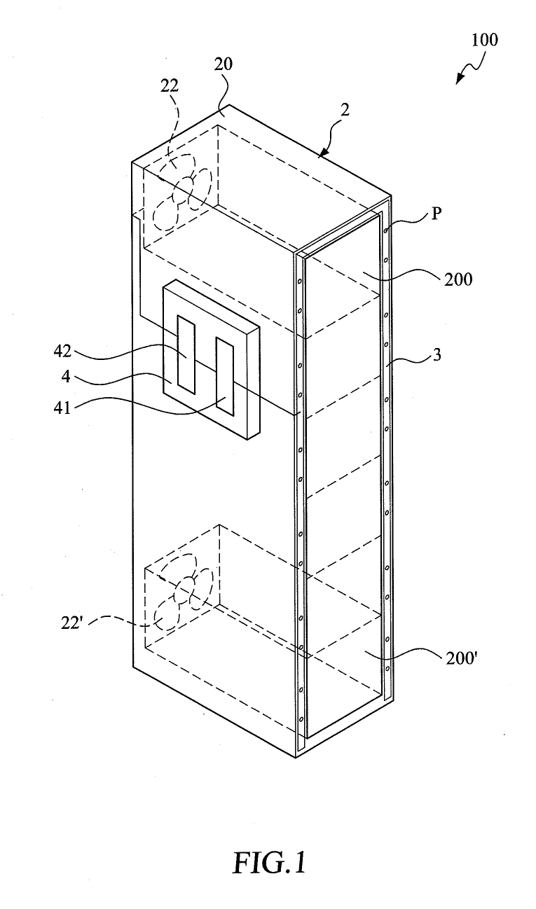

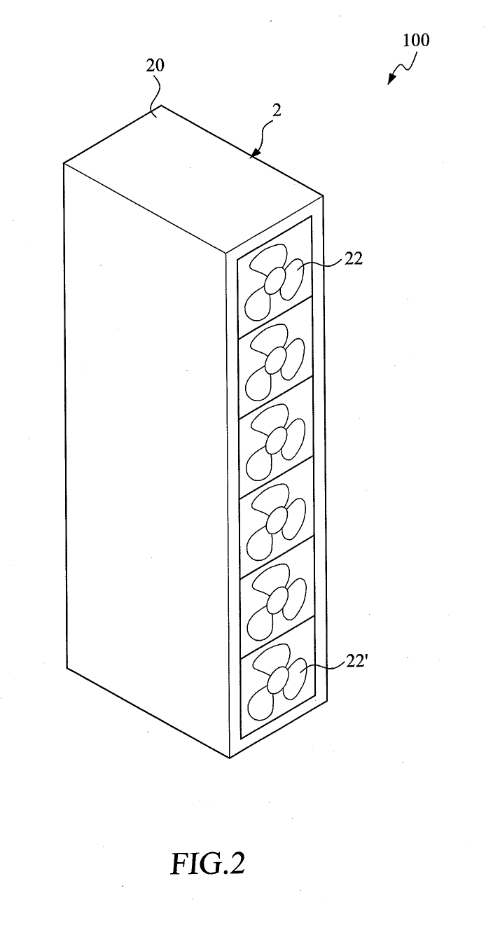

An air-flowing apparatus 100 of the first embodiment according to the present invention is shown in FIG. 1 to FIG. 2. FIG. 1 is one of the stereogram illustrating the first embodiment according to the present invention. FIG. 2 is another stereogram illustrating the first embodiment according to the present invention. The air-flowing apparatus 100 of the present invention includes a cabinet group 2, a temperature sensing device 3 and a temperature controlling device 4.

The cabinet group 2 has a cabinet 20 having a plurality of temperature controlling zones 200. Each temperature controlling zone 200 is provided with at least one speed-variable heat dissipation device 22 corresponding thereto. In this embodiment, each temperature controlling zone 200 is provided with a speed-variable heat dissipation device 22 corresponding thereto, and the plurality of speed-variable heat dissipation devices 22 are provided on the back of the cabinet 20. Of course, the embodiment is not to limit the present invention. The speed-variable heat dissipation devices may be provided on the front, side, top or bottom of the cabinet. In this embodiment, the speed-variable heat dissipation device 22 is a speed-variable heat dissipation fan of which the speed of their blades is variable.

In this embodiment, the temperature sensing device 3 is a temperature optical fiber cable. The temperature sensing device 3 is provided in proximity of the cabinet 20 and passing through each temperature controlling zone 200. The temperature sensing device 3 is provided with a plurality of temperature sensing members P to detect each temperature controlling zone 200 and generates a temperature signal corresponding to each temperature controlling zone 200.

The temperature controlling device 4 has a temperature signal receiving component 41 and a zone control outputting component 42. The temperature signal receiving component 41 is coupled to the temperature sensing device 3 to allow the temperature controlling device 4 to receive the temperature signal which is generated from the temperature sensing device 3, and thus the temperature signal receiving component 41 knows the temperature of each temperature sensing member P of each temperature controlling zone 200. Accordingly, the temperature controlling device 4 generates a controlling signal corresponding to the temperature of each temperature controlling zone 200. The zone control outputting component 42 is coupled to each speed-variable heat dissipation device 22 to output the controlling signal to each speed-variable heat dissipation device 22, and then each speed-variable heat dissipation device 22 changes speed of its fan. As a result, each temperature controlling zone 200 of the cabinet 20 is able to be separately controlled. For example, when temperature of a temperature zone 200′ of the cabinet 20 rises, the temperature controlling device 4 controls a speed-variable heat dissipation device 22′ corresponding to the temperature zone 200′ and increase speed thereof to increase rate of heat dissipation. And thus, temperature of a temperature zone 200′ is cooled.

### Second Embodiment

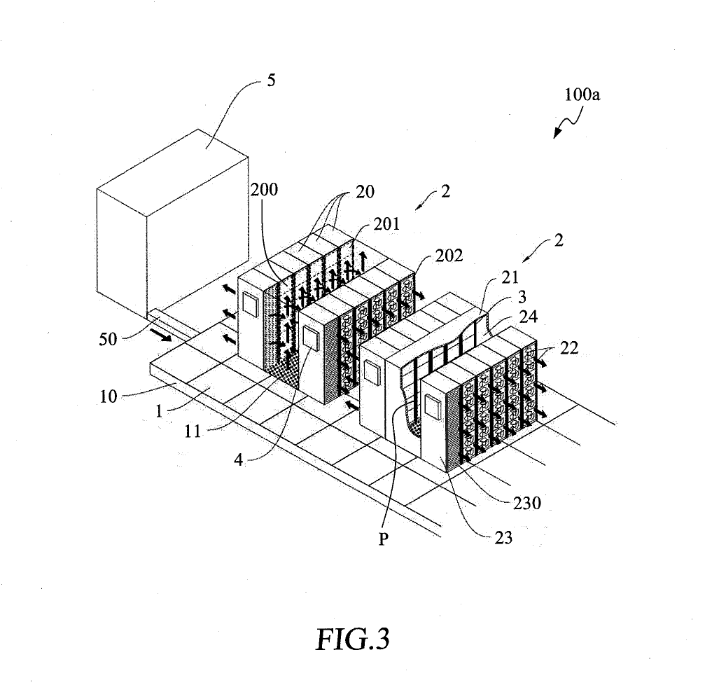

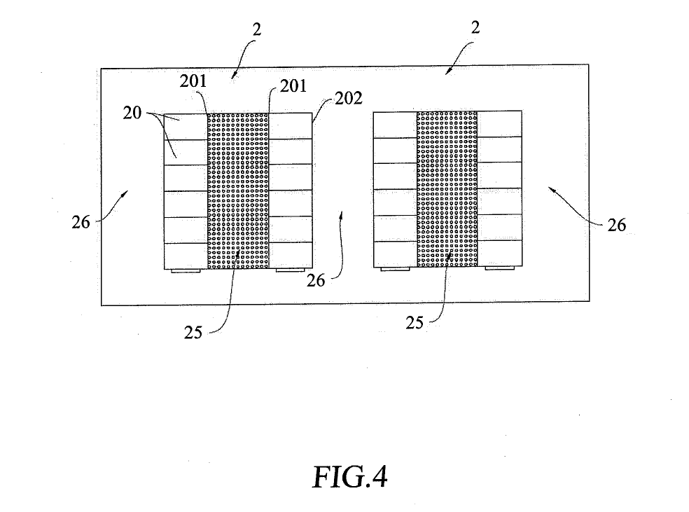

An air-flowing apparatus 100a of the second embodiment according to the present invention is shown in FIG. 3 to FIG. 4. FIG. 3 is a stereogram illustrating the second embodiment according to the present invention. FIG. 4 is a stereogram illustrating cold channel and hot channel of the second embodiment according to the present invention. The air-flowing apparatus 100a of the second embodiment according to the present invention includes:

A carrier board 1 is provided on a floor of an machine room and has an air channel 10 which is formed therein and is provided for flowing cold air.

A cabinet group 2 is provided above the carrier board 1. In this embodiment, a plurality of cabinet groups 2 are provided in parallel. Each cabinet group 2 includes a plurality of cabinets 20 and their front 201 correspond to each other. An air opening 11, transporting cold air, is formed on the carrier board 1 between a corresponding plurality of cabinets 20. A top of each cabinet group is provided with a top blocking part 21. A plurality of speed-variable heat dissipation device 22 are provided in a back 202 of each cabinet 20. Speed of the speed-variable heat dissipation device 22 is changeable by controlling. In this embodiment, a speed-variable heat dissipation device is a speed-variable fan. A side of each cabinet group 2 is connected with a refrigerating device 23, but this embodiment is not to limit the present invention. A refrigerating device may be provided in proximity to a cabinet group or be spaced apart from a cabinet group. The refrigerating device 23 is provided with a transporting part 230 and a back of the refrigerating device 23 is selectively provided with a speed-variable heat dissipation device 22. A side of each cabinet group is provided with a side blocking part 24 and a temperature controlling device 4, but the embodiment is not to limit the present invention. A temperature controlling device may be remotely or wirelessly control.

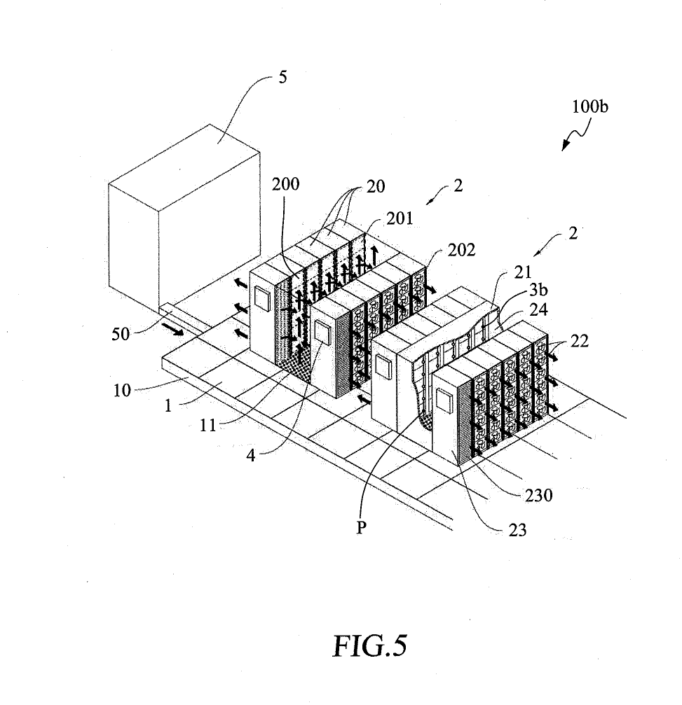

Each temperature controlling zone 200 and each refrigerating device 23 is provided with a temperature sensing device 3. The temperature sensing device 3 has a plurality of temperature sensing members P to sense temperature of each temperature controlling zone 200, and thus a temperature signal is generated and accurately transmitted to the temperature controlling device 4. In this embodiment, the temperature sensing device 3 is a temperature optical fiber cable connected to the temperature controlling device 4 as shown in FIG. 3. Of course, the embodiment is not to limit the present invention. A temperature sensing device 3b of an air-flowing apparatus 100b of the third embodiment according to the present invention shown in FIG. 5 is a plurality of temperature sensors. The plurality of temperature sensors are provided with a plurality of temperature sensing members P provided in each temperature controlling zone 200 to sense temperature of each temperature controlling zone 200.

A cold channel 25 is formed between the front 201 of the corresponding plurality of cabinets 20, and a hot channel 26 is formed between a back 202 of the cabinet group 20 and a back of another corresponding cabinet group 20.

An air flowing device 5 has an air tube 50 communicating with the air channel 10 of the carrier board 1, and thus the air flowing device 5 transports cold air through the air tube 50, the air channel 10 of the carrier board 1 and the air opening 11 to an machine room.

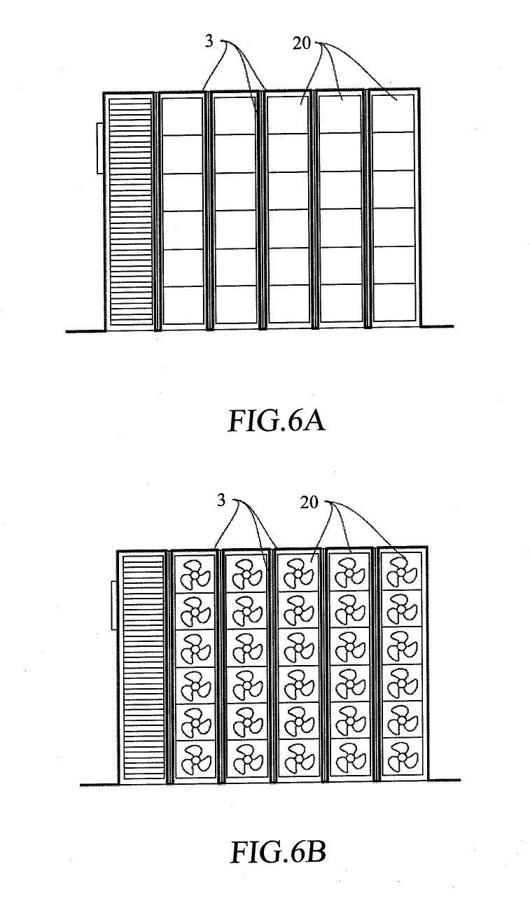

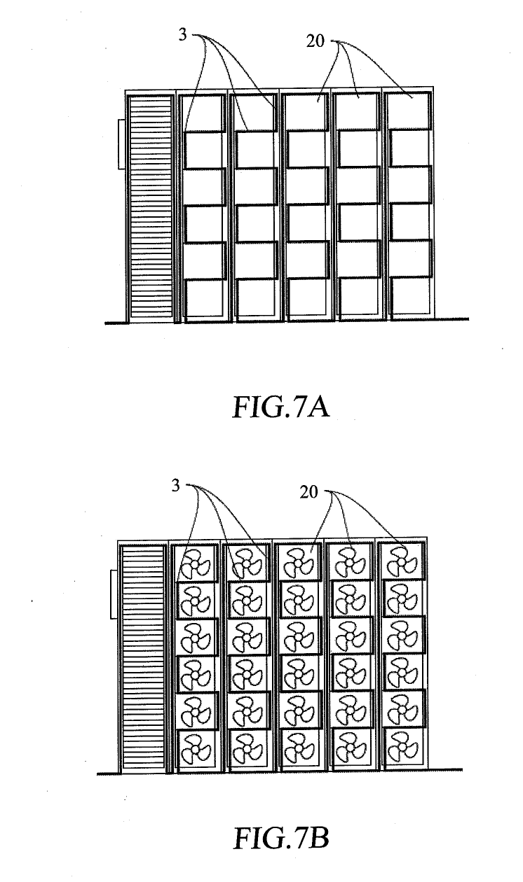

Refer to FIG. 6A, FIG. 6B, FIG. 7A and FIG. 7B. The temperature sensing device 3 is provided around the cabinets 20 as shown in FIG. 6A and FIG. 6B. Further, the temperature sensing device 3 is provided around each temperature controlling zone 200 of the cabinet 20, and then is provided around the next cabinet 20 as shown in FIG. 7A and FIG. 7B. Therefore, the temperature component 3 is provided with more temperature sensing members P in the cabinet 20 for more accurately sensing temperature variation of the cabinet 20.

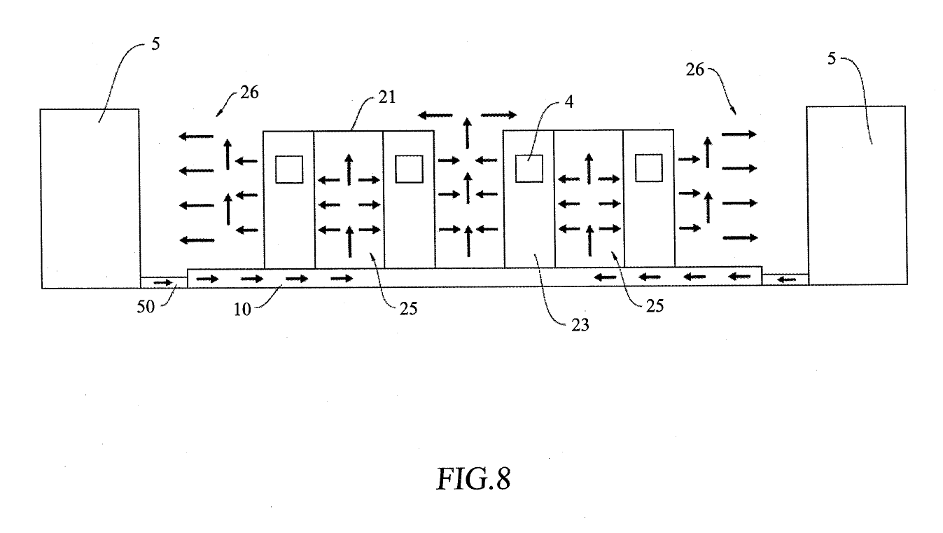

Refer to FIG. 8, FIG. 3 and FIG. 4. The operation of heat exchange of the air-flowing apparatus 100a will be described as follows. The air flowing device 5 produces cold air and transports cold air through the air tube 50, the air channel 10 and the air opening 11 to the cold channel 25 enclosed by the cabinet 20, the top blocking part 21 and the side blocking part 24. Cold air flows in the cold channel 25 to maintain temperature or lower heat which is generated from operation of a machine of the cabinet 20.

The temperature sensing device 3 provided around the cabinet 20 senses temperature variation of each temperature controlling zone 200 of each cabinet 20. The temperature sensing device 3 is provided with a preset temperature. If temperature of the cabinet 20 rises above the preset temperature, the temperature controlling device 4 determines which each temperature controlling zone 200 rises in temperature, and thus the temperature controlling device 4 drives the speed-variable heat dissipation device 22 corresponding to the temperature controlling zone 200. Accordingly, the heat generating from operation of a machine of the cabinet 20 is moved to hot channel 26. Further, when the temperature sensing device 3 senses that temperature of the cabinet 20 drops, the temperature sensing device 3 transmits temperature signal to the temperature controlling device 4, and then the temperature controlling device 4 controls the speed-variable heat dissipation device 22 corresponding to the temperature controlling zone 200 to decelerate speed thereof for power saving. Even when temperature of the cabinet 20 drops and is under the preset temperature, the temperature controlling device 4 controls to stop the speed-variable heat dissipation device 22 corresponding to the temperature controlling zone 200. By the above means, not only is power costs greatly reduced, but temperature of the machine room also is maintained or drops, and thus the machine is able to maintain normal operation. Furthermore, hot air of the hot channel 26 is moved outside the machine room, or is switched to cold air through the air flowing device 5 and then supplied to machine room.

Similarly, the refrigerating device 23 is able to sense temperature variation by the temperature sensing device 3. When temperature of the refrigerating device 23 rises, the temperature controlling device 4 receives the temperature signal from the temperature sensing device 3 and drives the refrigerating device 23 to produce cold air into the cold channel 25 through the transporting part 230. At the same time, hot air generated from operation of the refrigerating device 23 is moved to hot channel 26. Further, when temperature of the refrigerating device 23 drops, the temperature controlling device 4 controls the refrigerating device 23 to decelerate speed thereof. Furthermore, when temperature of the refrigerating device 23 drops and is under the preset temperature, the temperature controlling device 4 controls the refrigerating device 23 to stop operation for power saving.

Similarly, the air flowing device 5 operates in the same manner. When entire temperature inside machine room is already under the preset temperature, the temperature controlling device 4 controls the air flowing device 5 to decelerate speed thereof or stop operation.

By the above means, the present invention is able to accurately monitor temperature by accurately sensing temperature of each temperature controlling zone 200 of each cabinet 20 through a lot of temperature sensing members P of the temperature sensing device 3, and control speed of a speed-variable heat dissipation device 22, a refrigerating device 23 and air flowing device 5 respectively to perform micro control of temperature and heat exchange of gas. Thus the air-flowing apparatus has an effect of power saving and keeping normal operation of a machine, and reduces the probability of shutdown or failure. Further, the present invention which senses temperature of the cabinet 20 by a temperature optical fiber cable has advantage as follows. The temperature optical fiber cable itself is not conducting and is not influenced by the temperature, humidity and dust of environment, so the duration of the temperature optical fiber cable is very long. And thus the temperature sensing can be applied to an environment with explosive, flammable and other harsh factors or in an machine room which is with strong interference, corrosion, high temperature and explosion. Further, because the temperature optical fiber cable is a communications optical fiber cable, it does not need additional power supply and long distance monitoring. Furthermore, it is easy to build the temperature optical fiber cable. By the above describing, one the temperature optical fiber cable can achieve the effect of control, test and signal transmission.

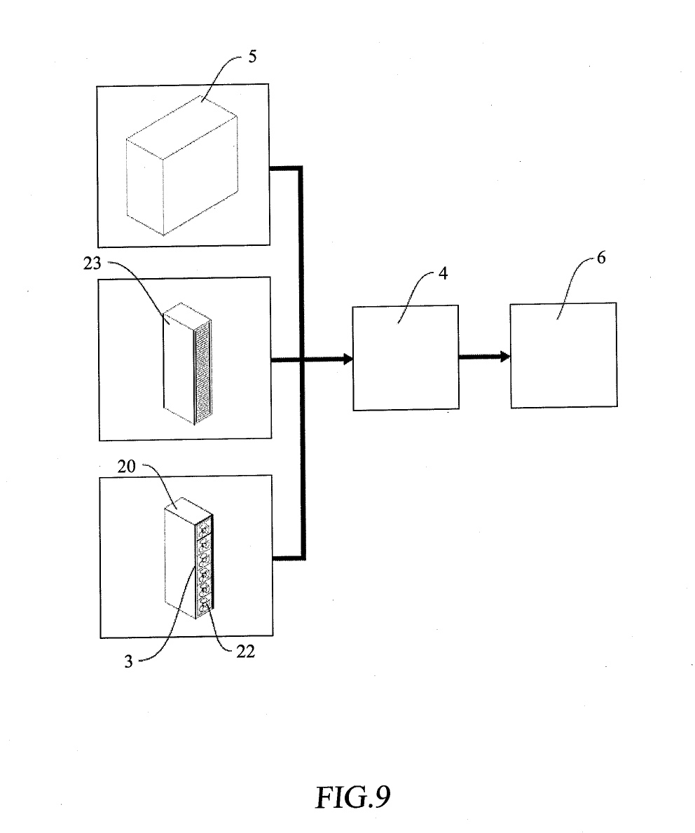

Refer to FIG. 9. The temperature controlling device 4 not only controls the speed-variable heat dissipation devices 22, the refrigerating device 23 and the air flowing device 5, but the temperature controlling device 4 also is remotely connected with a central control room 6. The central control room 6 remotely monitors the temperature optical fiber cable to sense temperature of the cabinet 20, the refrigerating device 23, and thus a user is able to remotely control the speed-variable heat dissipation devices 22, the refrigerating device 23, the air flowing device 5.

However, a person skilled in the art may make various modifications to the present invention. Those modifications still fall within the spirit and scope defined by the appended claims.

What is claimed is:

1. An air-flowing apparatus comprising:
a cabinet group having at least one cabinet, and each cabinet having a plurality of temperature controlling zones;
a temperature sensing device provided in proximity to each cabinet, and each of the plurality of temperature controlling zones provided with at least one temperature sensing member;
a plurality of speed-variable heat dissipation devices, each temperature controlling zone provided with at least one speed-variable heat dissipation device; and
a temperature controlling device having a temperature signal receiving component and a zone control outputting component, the temperature signal receiving component coupled to the temperature sensing device, and the zone control outputting component coupled to the speed-variable heat dissipation device.

2. The air-flowing apparatus as claimed in claim 1, wherein the temperature controlling device is remotely connected a central control room.

3. The air-flowing apparatus as claimed in claim 1, wherein the temperature sensing device is a temperature optical fiber cable.

4. The air-flowing apparatus as claimed in claim 1, wherein the temperature sensing device is a plurality of temperature sensors.

5. The air-flowing apparatus as claimed in claim 1, wherein a top of the cabinet group is provided with a top blocking part.

6. The air-flowing apparatus as claimed in claim 1, further comprising a carrier board and an air flowing device, the carrier board having an air channel which is formed therein, the air flowing device communicated with the air channel, the cabinet group including a plurality of cabinets and having a refrigerating device and a cold channel which is formed between the plurality of cabinets, the cold channel having an air opening, and the refrigerating device provided with a transporting part.

7. The air-flowing apparatus as claimed in claim 6, wherein a side of the cabinet group is configured with the refrigerating device.

8. The air-flowing apparatus as claimed in claim 6, wherein the temperature controlling device controls and is coupled to the speed-variable heat dissipation device, the refrigerating device and the air flowing device.

9. The air-flowing apparatus as claimed in claim 1, wherein a plurality of cabinet groups are provided, and each cabinet group has a corresponding temperature controlling device.

10. The air-flowing apparatus as claimed in claim 9, wherein there is provided with a hot channel between a back of the cabinet group and a back of another cabinet group.

11. The air-flowing apparatus as claimed in claim 3, wherein the temperature optical fiber cable is sinuously provided around the plurality of temperature controlling zones.

12. The air-flowing apparatus as claimed in claim 1, wherein the temperature controlling device separately controls the plurality of speed-variable heat dissipation devices.

13. The air-flowing apparatus as claimed in claim 6, wherein a back of the refrigerating device is provided with a speed-variable heat dissipation device whose rate of heat dissipation is changed and controlled by the temperature controlling device according to a sense of the temperature sensing device.
